(19) United States
(12) Patent Application Publication
(10) Pub. No.: US 2025/0212342 A1
(43) Pub. Date: Jun. 26, 2025

(54) DISPLAY CONVENIENT FOR MOUNTING AND REMOVING RIM

(71) Applicant: Shenzhen Joyhong Tech Co., Ltd, Shenzhen (CN)

(72) Inventor: Jianping Wang, Shenzhen (CN)

(21) Appl. No.: 19/074,654

(22) Filed: Mar. 10, 2025

(30) Foreign Application Priority Data
Jan. 20, 2025 (CN) 202520130566.X

(51) Int. Cl. H05K 5/02

(52) U.S. Cl. CPC H05K 5/0204; H05K 5/0217

(57) ABSTRACT

A display convenient for mounting and removing a rim is provided, including an outer rim body that can be freely assembled and quickly removed. The outer rim body includes two transverse rim body members and two longitudinal rim body members; the two transverse rim body members and the two longitudinal rim body members are provided with magnetic suction mechanisms convenient for mounting and removal; and the transverse rim body members and the two longitudinal rim body members are in attracting connection to a shell of the display through the magnetic suction mechanisms. Magnets are embedded into the receiving slots and are in direct contact with the shell of the display, which eliminates a problem of a physical spacing between the magnetic components in a traditional design, thereby significantly improving the suction firmness.

### TECHNICAL FIELD

The present disclosure relates to the technical field of display accessories, and in particular, to a display convenient for mounting and removing a rim.

### BACKGROUND

Stationary display devices such as a television are used at fixed positions in an environment of a user (a house) will not be replaced for long time. On the other hand, due to indoor decoration, moving to a new house, and other reasons, the environment of the user may frequently change. Therefore, to select a display device, the user selects a simple design that the user will not be easily tired of and will not be greatly affected by a surrounding environment.

In order to solve the above problems, according to a “display device and a frame” disclosed in patent No. “U.S. Ser. No. 10/750,624B2”, several first magnetic components mg1 (which can be magnetic materials, such as permanent magnets or electromagnets) are arranged inside edges (a periphery) of a display (a display device) body. Four rims are arranged at the periphery of the display (display apparatus) body. Each rim has a hollow region therein. Several second magnetic components mg2 (which can be magnetic materials, such as permanent magnets or electromagnets) are arranged inside the hollow regions. The four rims are respectively attached and fixed to the edges (periphery) of the display (display apparatus) body, and the second magnetic components mg2 on the rims attract and are fixed to the first magnetic components mg1 on the edges (periphery) of the display (display apparatus) body. Finally, the edges (periphery) of the display (display apparatus) body are wrapped by the four rims.

However, in practical use, this display device and framework still have the following defects:

1) The first magnetic components mg1 (which can be magnetic materials, such as permanent magnets or electromagnets) need to be arranged inside the edges (periphery) of the display (display apparatus) body in advance, that is, the magnetic components need to be fixed inside the edges (periphery) of the display (display apparatus) body through adhesion, welding, fasteners, and the like. This will add procedures such as production, mold opening, and assembling of a display (display apparatus), so that internal structures are more complex, and high requirements are put forward to production and assembling. Therefore, defective products may increase, and the production costs is higher.

2) The second magnetic components mg2 (which can be magnetic materials, such as permanent magnets or electromagnets) need to be arranged inside the hollow regions g1 inside the rims in advance. This will add procedures such as production, mold opening, and assembling of the rims, so that internal structures are more complex, and high requirements are put forward to production and mounting. Therefore, defective products may increase, and the production costs is higher.

3) The second magnetic components mg2 are arranged in the hollow regions g1 inside the rims, and the first magnetic components mg1 are arranged inside the edges (periphery) of the display (display apparatus) body, causing a distance between the first magnetic components mg1 and the second magnetic components mg2, so that they are physically separated. Therefore, even if the rims and the display (display apparatus) attract together under the mutual attraction of the first magnetic components mg1 and the second magnetic components mg2, their attraction forces are low. During transportation, handling, movement, and mounting, collision and vibration forces can be generated, which can easily cause displacement, leading to gaps between the four rims, or leading to gaps between the four rims and the edges (periphery) of the display (display apparatus) body. This affects the appearance of the product. In case of great collision or high vibration forces, the rims can even directly fall off.

4) Meanwhile, a person skilled in the art can know that each magnetic body has two magnetic poles, namely a magnetic south pole (S) and a magnetic north pole (N). If the first magnetic components mg1 inside the edges (periphery) of the display body of the Samsung in South Korea have the south poles (S), the second magnetic components mg2 on the four brims need to have the magnetic north poles (N), in order to attract and be fixed with each other. In this design, the rims and the display (display apparatus) need to be completely matched, and cannot be replaced. If a consumer intends to replace the rims, the customer has no other choices, so it has a limitation and cannot meet a need of the customer for personalized transformation on the rims.

### SUMMARY

The present disclosure aims to provide a display convenient for mounting and removing a rim, to solve the problems mentioned in the above background section.

To achieve the above objectives, the present disclosure provides the following technical solution: A display convenient for mounting and removing a rim includes a display. The display is composed of a screen component and a shell, and the screen component is mounted inside the shell;
the display further comprises an outer rim body that is freely assembled and quickly removed; the outer rim body includes two transverse rim body members and two longitudinal rim body members; the two transverse rim body members and the two longitudinal rim body members are provided with magnetic suction mechanisms convenient for mounting and removal; and the transverse rim body members and the two longitudinal rim body members are in attracting connection to the shell of the display through the magnetic suction mechanisms.

In a preferred solution of the present disclosure, the shell is made of a non-metal material, a metal material, or a magnetic material.

In a preferred solution of the present disclosure, assembling ends of the transverse rim body members and assembling ends of the longitudinal rim body members are 45° oblique cut ends; surfaces of the oblique cut ends of the transverse rim body members are fixedly connected with plugging protrusion; surfaces of the oblique cut ends of the longitudinal rim body members are provided with plugging grooves; and when the transverse rim body members are enclosed with the longitudinal rim body members, the plugging protrusions are in plugged connection to the plugging grooves.

In a preferred solution of the present disclosure, hollow square reinforcing ribs are arranged on inner sides of the transverse rim body members and inner sides of the longitudinal rim body members; convex columns fixedly connected to inner sides of the rim body members are arranged inside the reinforcing ribs; and the convex columns are provided with receiving slots.

In a preferred solution of the present disclosure, convex grooved lines that apply a compression force to the shell of the display and play a fixing role are arranged on inner sides of the transverse rim body members and inner sides of the longitudinal rim body members, and cross sections of the transverse rim body members and cross sections of the longitudinal rim body members are U-shaped.

In a preferred solution of the present disclosure, at least one of the transverse rim body members and the longitudinal rim body members is made of a magnetic material, and at least one of the transverse rim body members and the longitudinal rim body members is made of a metal material.

In a preferred solution of the present disclosure, each magnetic suction mechanism is of an embedded magnetic suction structure; each magnetic suction mechanism includes a magnet embedded inside a receiving slot and having a matching shape; when the transverse rim body members and the longitudinal rim body members are flatly enclosed outside the display, the magnets magnetically attract the shell of the display; and when the magnets are embedded inside the receiving slots, magnetic poles are not limited.

In a preferred solution of the present disclosure, each magnetic suction mechanism is of an assembled magnetic suction structure; each magnetic suction mechanism includes first magnetic suction ends at two ends of each transverse rim body member; and the first magnetic suction ends are in magnetic suction connection to second magnetic suction ends at two ends of each longitudinal rim body member.

Compared with the prior art, the present disclosure has the beneficial effects below:

1) In the present disclosure, the convex columns and the receiving slots are arranged on the inner side of the rim, so that magnetic components can be conveniently embedded and replaced. This not only simplifies production and mounting processes, but also lowers a requirement for production accuracy, thereby reducing defective products and increasing the yield rate. Furthermore, polarities of the magnetic components are not limited, and a user can freely replace the rim according to a need, to meet a personalization need.

2) The horizontal and longitudinal rim body members of the rim of the present disclosure achieve stable assembled connection through the plugging design of the 45° oblique cut ends. The internal hollow square reinforcing rib and convex column design further enhances the structural strength of the rim, so that the rim is less likely to deformation or damage during transportation, handling, movement, and mounting. Meanwhile, the arranged convex grooved lines provide an additional extrusion force for the shell of the display, which ensures that the rim does not easily move or fall off under an external force.

3) In the present disclosure, the embedded and assembled magnetic suction mechanisms are used to flexibly select suction between the rim and the shell of the display. The magnets are embedded inside the receiving slots and are in direct contact with the shell of the display, which eliminates a physical spacing between the magnetic components in the traditional design, thereby greatly improving the suction firmness. Even under a high external force, the rim can also be stable and does not easily fall off.

4) In the present disclosure, the horizontal and longitudinal rim body members of the rim can be made of the non-metal material, the metal material, or the magnetic material, which provides diversified material choices. This not only reduces the production costs, but also makes the rim lighter and easier to replace and maintain. A user can select rims with different materials and colors according to a personal preference, thus achieving a personalized indoor decoration effect and adapting to different user environment changes.

### BRIEF DESCRIPTION OF THE DRAWINGS

FIG. 1 is a schematic structural diagram of the present disclosure;

FIG. 2 is a schematic structural diagram I of the present disclosure;

FIG. 3 is a schematic exploded diagram of the present disclosure;

FIG. 4 is a schematic structural diagram of an outer rim body of the present disclosure;

FIG. 5 is a schematic structural diagram of a transverse rim body member of the present disclosure;

FIG. 6 is a schematic structural diagram of a longitudinal rim body member of the present disclosure; and

FIG. 7 is a schematic structural diagram of Embodiment 2 of the present disclosure.

In the drawings: 100: display; 110: screen component; 120: shell; 200: outer rim body; 210: transverse rim body member; 211: plugging protrusion; 220: longitudinal rim body member; 221: plugging groove; 230: oblique cut end; 240: reinforcing rib; 250: convex column; 251: receiving slot; 260: convex grooved line; 300: magnetic suction mechanism; 310: magnet; 320: first magnetic suction end; and 330: second magnetic suction end.

### DETAILED DESCRIPTION OF THE EMBODIMENTS

The following clearly and completely describes the technical solutions in the embodiments of the present disclosure with reference to the accompanying drawings in the embodiments of the present disclosure. Apparently, the described embodiments are some of the embodiments of the present disclosure rather than all of the embodiments. Based on the embodiments of the present disclosure, all other embodiments obtained by those of ordinary skilled in the art without creative efforts fall within the protection scope of the present disclosure.

### Embodiment 1

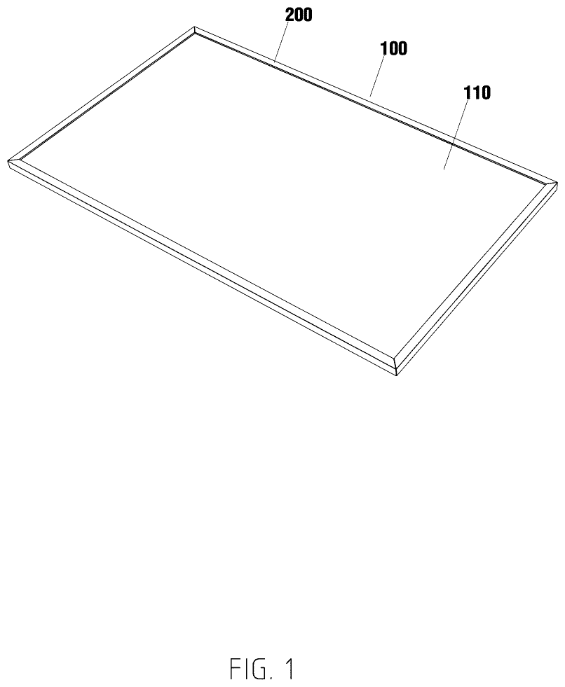

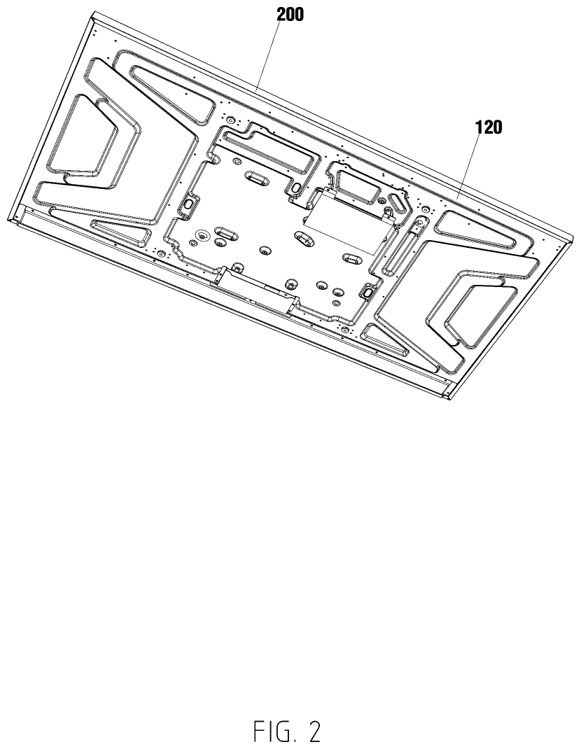

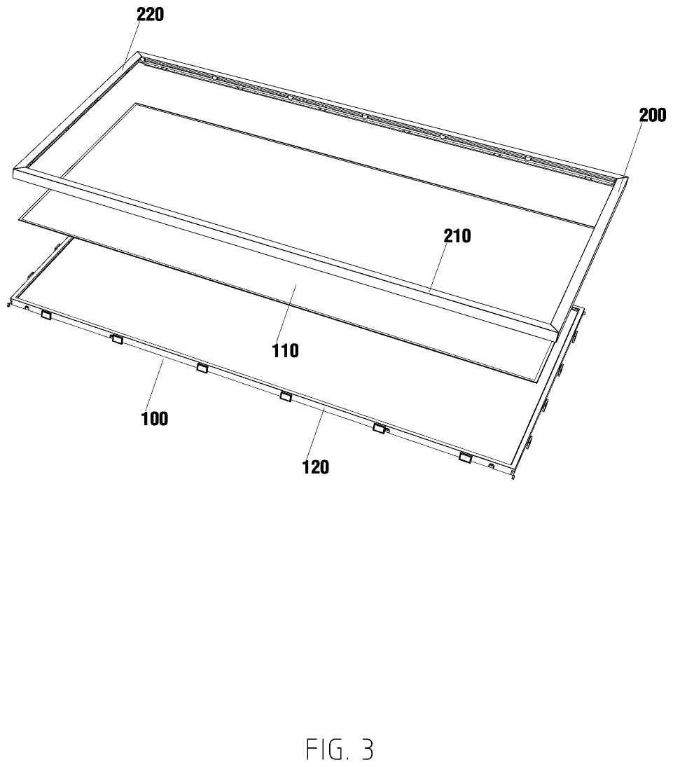

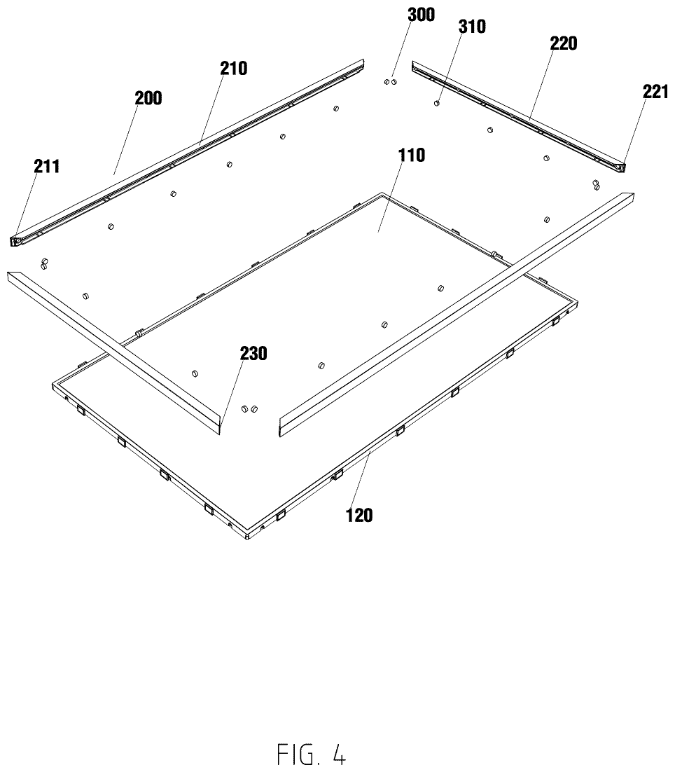

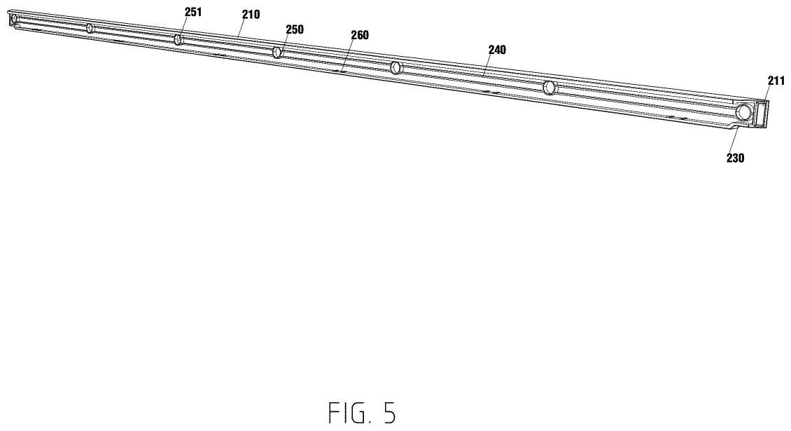

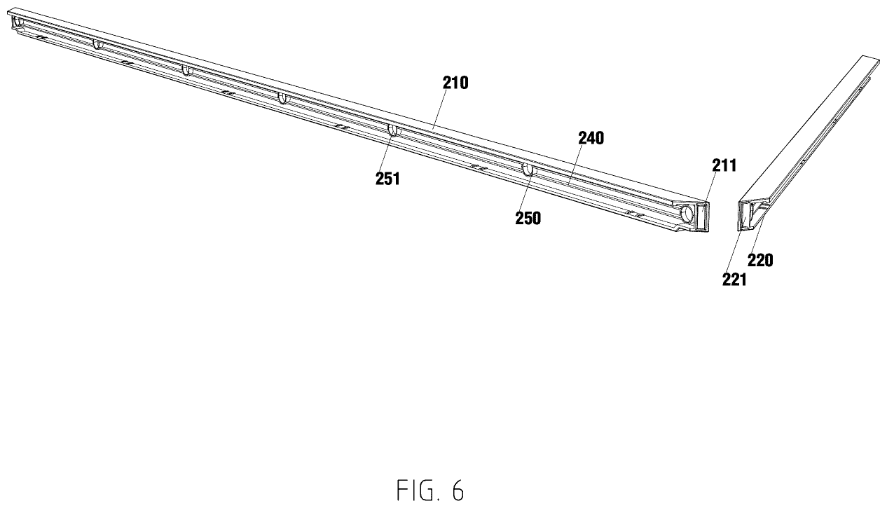

Referring to FIG. 1 to FIG. 6, the present disclosure provides a technical solution: A display convenient for mounting and removing a rim includes a display 100. The display 100 is composed of a screen component 110 and a shell 120, and the screen component 110 is mounted inside the shell 120.

Specifically, the display is composed of the screen component 110 and the shell 120. After the screen component 110 is mounted inside the shell 120, the screen component 110 is responsible for displaying images, and the shell 120 can protect and support the screen component 110, so that the display can be used normally in daily life.

In this embodiment, the shell 120 is made of a metal or magnetic material.

Specifically, the shell 120 is made of the metal or magnetic material. By specifically selecting the material, the shell 120 has a magnetic property or a characteristic of being sucked by a magnetic substance. When the shell 120 is made of the magnetic material, the shell 120 and the rim can magnetically attract each other, thereby achieving rapid mounting and removal of the metal rim. When the shell 120 is made of the metal material, the shell 120 can attract a rim with a magnetic suction structure, which can also achieve flexible mounting and removal of the rim on the display.

The display further includes an outer rim body 200 that can be freely assembled and quickly removed. The outer rim body 200 includes two transverse rim body members 210 and two longitudinal rim body members 220. The two transverse rim body members 210 and the two longitudinal rim body members 220 are provided with magnetic suction mechanisms 300 convenient for mounting and removal. The transverse rim body members 210 and the two longitudinal rim body members 220 are in attracting connection to the shell 120 of the display 100 through the magnetic suction mechanisms 300.

Specifically, the rim is composed of the two transverse rim body members 210 and the two longitudinal rim body members 220, so that the rim can be flexibly assembled. By the arrangement of different types of magnetic suction mechanisms 300, the rim can be conveniently and flexibly sucked to the shell 120 of the display and is also convenient to remove and replace, which provides great convenience for a user.

In this embodiment, the shell 120 is made of the non-metal material, and assembling ends of the transverse rim body members 210 and assembling ends of the longitudinal rim body members 220 are 45° oblique cut ends 230. Surfaces of the oblique cut ends 230 of the transverse rim body members 210 are fixedly connected with plugging protrusion 211. Surfaces of the oblique cut ends 230 of the longitudinal rim body members 220 are provided with plugging grooves 221. When the transverse rim body members 210 are enclosed with the longitudinal rim body members 220, the plugging protrusions 211 are in plugged connection to the plugging grooves 221.

Specifically, the assembling ends of the transverse rim body members 210 and the assembling ends of the longitudinal rim body members 220 are designed as the 45° oblique cut ends 230, so that the rim body members can form tight angles during assembling, without causing protrusions or burrs that may scratch a user. Meanwhile, the structural strength of the rim is enhanced. Moreover, when the transverse rim body members 210 and the longitudinal rim body members 220 are enclosed and assembled, the plugging protrusions 211 are plugged into the plugging grooves 221, so that the assembling between the rim body members is more stable and less likely to loosen, thereby improving the overall stability of the rim, and providing guarantee for normal use of the rim.

In this embodiment, hollow square reinforcing ribs 240 are arranged on inner sides of the transverse rim body members 210 and inner sides of the longitudinal rim body members 220. Convex columns 250 fixedly connected to inner sides of the rim body members are arranged inside the reinforcing ribs 240. The convex columns 250 are provided with receiving slots 251.

Specifically, the hollow square reinforcing ribs 240 are arranged on the transverse rim body members 210 and the longitudinal rim body members 220, so that the structural strength of the rim body members is enhanced. Furthermore, the rim can better disperse stress under an external force to prevent deformation or damage. In addition, the receiving slots 251 provided in the convex columns 250 provide convenience for the mounting of the magnetic suction mechanisms 300, so that the magnets can be firmly embedded into the rim. Furthermore, when the rim body members are sucked to the shell 120, a staggered structure will not be formed, which ensures the fitness between the rim and the shell 120 during mounting.

In this embodiment, convex grooved lines 260 that apply a compression force to the shell 120 of the display 100 and play a fixing role are arranged on inner sides of the transverse rim body members 210 and inner sides of the longitudinal rim body members 220, and cross sections of the transverse rim body members 210 and cross sections of the longitudinal rim body members 220 are U-shaped.

Specifically, the U-shaped cross sections make the rim body lighter and can be mounted on the shell 120 more rapidly. When the shell 120 is assembled with the rim body, the convex grooved lines 260 can cause the outer shell 120 to apply an additional compression force to the rim body, thereby providing a better fixing effect. By cooperation with the magnetic suction mechanisms 300, the stability of suction between the rim and the shell 120 can be further improved.

In this embodiment, at least one of the transverse rim body members 210 and the longitudinal rim body members 220 is made of a magnetic material, and at least one of the transverse rim body members 210 and the longitudinal rim body members 220 is made of a metal material.

Specifically, when at least one of the transverse rim body members 210 and the longitudinal rim body members 220 is made of the magnetic material, and at least one of the transverse rim body members 210 and the longitudinal rim body members 220 is made of the metal material, the transverse rim body members 210 and the longitudinal rim body members 220 can be assembled and enclosed outside the shell 120 without the magnetic suction mechanisms 300, which further improves the flexibility of removal of the rim and provides more choices for a user. Meanwhile, the rim body members with the simplified structures can also reduce the production costs of the rim.

In this embodiment, each magnetic suction mechanism 300 is of an embedded magnetic suction structure. Each magnetic suction mechanism 300 includes a magnet 310 embedded inside a receiving slot 251 and having a matching shape. When the transverse rim body members 210 and the longitudinal rim body members 220 are flatly enclosed outside the display 100, the magnets 310 magnetically attract the shell 120 of the display 100. When the magnets 310 are embedded inside the receiving slots 251, magnetic poles are not limited.

Specifically, the magnetic suction mechanisms 300 uses the embedded magnetic suction structures. The magnets 310 are embedded inside the receiving slots 251 and adapt to the shapes of the receiving slots 251, so that the magnets 310 can be firmly fixed inside the rim body and do not easily fall off or move. Moreover, the magnetic poles of the magnets 310 are not limited, which provides higher flexibility for a user and improves the adaptability of the rim body, so that a need of a customer for personalized transformation on the rim is better met.

### Embodiment 2

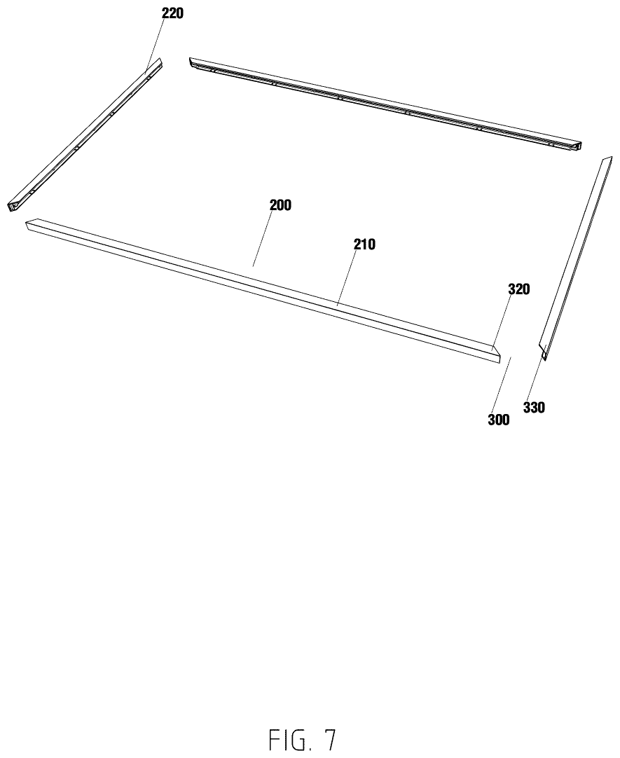

Referring to FIG. 7, a technical feature that distinguishes this embodiment from Embodiment 1 is that each magnetic suction mechanism 300 is of an assembled magnetic suction structure. Each magnetic suction mechanism 300 includes first magnetic suction ends 320 at two ends of each transverse rim body member 210. The first magnetic suction ends 320 are in magnetic suction connection to second magnetic suction ends 330 at two ends of each longitudinal rim body member 220.

Specifically, each magnetic suction mechanism 300 uses the assembled magnetic suction structure. The first magnetic suction ends 320 at the two ends of each transverse rim body member 210 and the second magnetic suction ends 330 at the two ends of each longitudinal rim body member 220 are used for magnetic suction, so that the rim can be stably connected through the interaction between the magnetic suction ends during assembling. Meanwhile, this assembled magnetic suction structures also provide convenience for removal and replacement of the rim.

Content that is not described in detail in this specification belongs to the existing technology known to those skilled in the art. Although the present disclosure has been described in detail with reference to the foregoing embodiments, those skilled in the art can still make modifications to the technical solutions described in the foregoing respective embodiments or make equivalent replacements to some technical features therein. Any modification, equivalent replacement, improvement, and the like made within the spirit and principle of the present invention shall fall within the protection scope of the present disclosure.

What is claimed is:

1. A display convenient for mounting and removing a rim, comprising a display (100), wherein the display (100) is composed of a screen component (110) and a shell (120), and the screen component (110) is mounted inside the shell (120);
the display further comprises an outer rim body (200) that is freely assembled and quickly removed; the outer rim body (200) comprises two transverse rim body members (210) and two longitudinal rim body members (220); the two transverse rim body members (210) and the two longitudinal rim body members (220) are provided with magnetic suction mechanisms (300) convenient for mounting and removal; and the transverse rim body members (210) and the two longitudinal rim body members (220) are in attracting connection to the shell (120) of the display (100) through the magnetic suction mechanisms (300).

2. The display convenient for mounting and removing the rim according to claim 1, wherein the shell (120) is made of a non-metal material, a metal material, or a magnetic material.

3. The display convenient for mounting and removing the rim according to claim 1, wherein assembling ends of the transverse rim body members (210) and assembling ends of the longitudinal rim body members (220) are 45° oblique cut ends (230); surfaces of the oblique cut ends (230) of the transverse rim body members (210) are fixedly connected with plugging protrusion (211); surfaces of the oblique cut ends (230) of the longitudinal rim body members (220) are provided with plugging grooves (221); and when the transverse rim body members (210) are enclosed with the longitudinal rim body members (220), the plugging protrusions (211) are in plugged connection to the plugging grooves (221).

4. The display convenient for mounting and removing the rim according to claim 1, wherein hollow square reinforcing ribs (240) are arranged on inner sides of the transverse rim body members (210) and inner sides of the longitudinal rim body members (220); convex columns (250) fixedly connected to inner sides of the rim body members are arranged inside the reinforcing ribs (240); and the convex columns (250) are provided with receiving slots (251).

5. The display convenient for mounting and removing the rim according to claim 1, wherein convex grooved lines (260) that apply a compression force to the shell (120) of the display (100) and play a fixing role are arranged on inner sides of the transverse rim body members (210) and inner sides of the longitudinal rim body members (220), and cross sections of the transverse rim body members (210) and cross sections of the longitudinal rim body members (220) are U-shaped.

6. The display convenient for mounting and removing the rim according to claim 1, wherein at least one of the transverse rim body members (210) and the longitudinal rim body members (220) is made of a magnetic material, and at least one of the transverse rim body members (210) and the longitudinal rim body members (220) is made of a metal material.

7. The display convenient for mounting and removing the rim according to claim 1, wherein each magnetic suction mechanism (300) is of an embedded magnetic suction structure; each magnetic suction mechanism (300) comprises a magnet (310) embedded inside a receiving slot (251) and having a matching shape; when the transverse rim body members (210) and the longitudinal rim body members (220) are flatly enclosed outside the display (100), the magnets (310) magnetically attract the shell (120) of the display (100); and when the magnets (310) are embedded inside the receiving slots (251), magnetic poles are not limited.

8. The display convenient for mounting and removing the rim according to claim 1, wherein each magnetic suction mechanism (300) is of an assembled magnetic suction structure; each magnetic suction mechanism (300) comprises first magnetic suction ends (320) at two ends of each transverse rim body member (210); and the first magnetic suction ends (320) are in magnetic suction connection to second magnetic suction ends (330) at two ends of each longitudinal rim body member (220).
